(19) United States
(12) Patent Application Publication
(10) Pub. No.: US 2025/0346481 A1
(43) Pub. Date: Nov. 13, 2025

(54) DRIVE ELEMENT AND OPTICAL DEFLECTION ELEMENT

(71) Applicant: Panasonic Intellectual Property Management Co., Ltd., Osaka (JP)

(72) Inventors: KAITO HANATANI, Osaka (JP); KENSUKE MIHARA, Osaka (JP); TAKAMI ISHIDA, Osaka (JP)

(21) Appl. No.: 19/275,730

(22) Filed: Jul. 21, 2025

Related U.S. Application Data
(63) Continuation of application No. PCT/JP2024/001670, filed on Jan. 22, 2024.

(30) Foreign Application Priority Data
Feb. 10, 2023 (JP) 2023-018973

(51) Int. Cl. B81B 3/00; B81C 1/00; G02B 26/08

(52) U.S. Cl. CPC B81B 3/0072; B81C 1/00666; G02B 26/0858; B81B 2201/042; B81B 2203/0154; B81B 2203/04; B81B 2203/058; B81C 2201/0112; B81C 2201/0132

(57) ABSTRACT

In a drive element, suppressing breakage in a support part due to stress concentration caused by torsion of the support part. The drive element includes a movable part allowed to be turned about a turn axis, a fixture, support part extending along the turn axis and connecting the movable part and the fixture, and a drive part that turns the movable part about the turn axis. A plurality of recesses extending in a direction away from the movable part is formed in side surface of the support part side by side in a thickness direction of the support part. The recess formed in a first region including at least the center in a thickness direction of the side surface of the support part has a smaller size than the recess formed in a second region other than the first region on the side surface of the support part.

### BACKGROUND

### 1. Technical Field

The present disclosure relates to a drive element that turns a movable part about a turn axis, and an optical deflection element using the drive element.

### 2. Description of the Related Art

In recent years, a drive element has been developed in which a movable part is turned using a micro electro mechanical system (MEMS) technique. This type of drive element enables light incident on a reflecting surface to be swept at a predetermined deflection angle with the reflecting surface disposed on the movable part. This type of drive element is mounted on an image display device such as a head-up display or a head-mounted display. Besides this, this type of drive element can also be used for a laser radar or the like that detects an object using laser light.

Known examples of this type of drive element includes a drive element of a type of turning a movable part using a so-called tuning fork vibrator. This drive element includes the movable part that is supported to be able to be turned by a support part extending along a turn axis. When the tuning fork vibrator is driven, the support part is turned together with the movable part that is turned about the turn axis. Consequently, the reflecting surface disposed on the movable part is turned. A drive element configured as described above is described in PTL 1 below, for example.

### CITATION LIST

### Patent Literature

PTL 1: International Publication No. 2013/046612

### SUMMARY

The drive element configured as described above has an outer shape formed by etching a substrate by the Bosch process. The drive element formed by the etching has a side surface in which many scallops (recesses) are formed side by side in a thickness direction of the substrate.

Meanwhile, when the movable part is driven by the tuning fork vibrator in the drive element configured as described above, the support part is twisted. Consequently, stress concentrates near the center in the thickness direction in the side surface of the support part. For this reason, when the scallop (recess) is generated in the side surface of the support part as described above, the concentrated stress described above may cause breakage starting from the scallop (recess) near the center of the side surface.

In view of such a problem, it is an object of the present disclosure to provide a drive element capable of suppressing breakage of a support part due to stress concentration caused by torsion of the support part, and an optical deflection element using the drive element.

A first aspect of the present disclosure relates to a drive element. The drive element according to the present aspect includes a movable part allowed to be turned about a turn axis, a fixture, a support part extending along the turn axis and connecting the movable part and the fixture, and a drive part that turns the movable part about the turn axis. The support part includes a side surface including a plurality of recesses, the plurality of recesses extending in a direction away from the movable part and being disposed side by side in a thickness direction of the support part, and the plurality of recesses includes a first recess formed in a first region including at least the center of the side surface of the support part in the thickness direction, and a second recess formed in a second region other than the first region of the side surface of the support part, the first recess having a smaller size than the second recess.

When torsion occurs in the support part due to a turn of the movable part, stress concentrates near the center of the side surface of the support part. At this time, when the recess formed in the side surface of the support part is large in size, breakage may occur starting from the recess near the center of the side surface. In contrast, the drive element according to the present aspect includes the first recess formed in the first region including the center where the stress is most concentrated when the support part is twisted, and the first recess having a smaller size than the second recess formed in the second region other than the first region. Consequently, strength near the center is increased to enable suppressing breakage in the side surface of the support part due to stress concentration.

A second aspect of the present disclosure relates to an optical deflection element. The optical deflection element according to the present aspect includes the drive element according to the first aspect and a reflecting surface disposed on the movable part.

The optical deflection element according to the present aspect enables light to be deflected and swept by the reflecting surface.

As described above, the drive element and the optical deflection element of the present disclosure enables providing a drive element and an optical deflection element that are each capable of suppressing breakage of a support part due to stress concentration caused by torsion of the support part.

### BRIEF DESCRIPTION OF THE DRAWINGS

FIG. 1 is a perspective view schematically illustrating a configuration of a drive element according to an exemplary embodiment;

FIG. 2A is a diagram schematically illustrating a procedure for molding a base material of a drive element according to an exemplary embodiment;

FIG. 2B is a diagram schematically illustrating a procedure for molding the base material of the drive element according to the exemplary embodiment;

FIG. 2C is a diagram schematically illustrating a procedure for molding the base material of the drive element according to the exemplary embodiment;

FIG. 3 is a diagram schematically illustrating a cross section of a support part according to a comparative example, taken along a plane parallel to an X-Z plane;

FIG. 4 is a diagram schematically illustrating a cross section of a support part according to the exemplary embodiment, taken along a plane parallel to the X-Z plane;

FIG. 5A is a schematic diagram illustrating an example in which a recess formed in a side surface according to the exemplary embodiment has a size corresponding to a depth of the recess;

FIG. 5B is a schematic diagram illustrating an example in which a recess formed in a side surface according to the exemplary embodiment has a size corresponding to a height of the recess;

FIG. 6 is a diagram schematically illustrating a cross section of a support part according to a first modification, taken along a plane parallel to the X-Z plane;

FIG. 7 is a diagram schematically illustrating a cross section of a support part according to a second modification, taken along a plane parallel to the X-Z plane;

FIG. 8 is a diagram schematically illustrating a cross section of a support part according to a third modification, taken along a plane parallel to the X-Z plane; and

FIG. 9 is a perspective view schematically illustrating a configuration of a drive element according to another modification.

### DETAILED DESCRIPTIONS

Description below of an exemplary embodiment will further reveal effects or meanings of the present disclosure. However, the exemplary embodiment described below is merely an example for implementing a technical idea of the present disclosure, and thus the present disclosure is not limited to the example described in the exemplary embodiment described below at all.

The exemplary embodiment of the present disclosure will be described below with reference to the drawings.

The exemplary embodiment below shows a drive element with a movable part on which a reflecting surface is disposed to form an optical deflection element. For convenience, X, Y, and Z axes orthogonal to each other are added to each drawing. A Y-axis direction is parallel to a turn axis of the drive element, and a Z-axis direction is perpendicular to the reflecting surface disposed on the movable part. Hereinafter, “upper” represents a positive direction of the Z-axis, and “lower” represents a negative direction of the Z-axis. An “upper side” refers to being positioned in the positive direction of the Z-axis with respect to a certain point, and a “lower side” refers to being positioned in the negative direction of the Z-axis with respect to a certain point. An “upper surface” represents a surface facing the positive direction of the Z-axis, and a “lower surface” represents a surface facing the negative direction of the Z-axis.

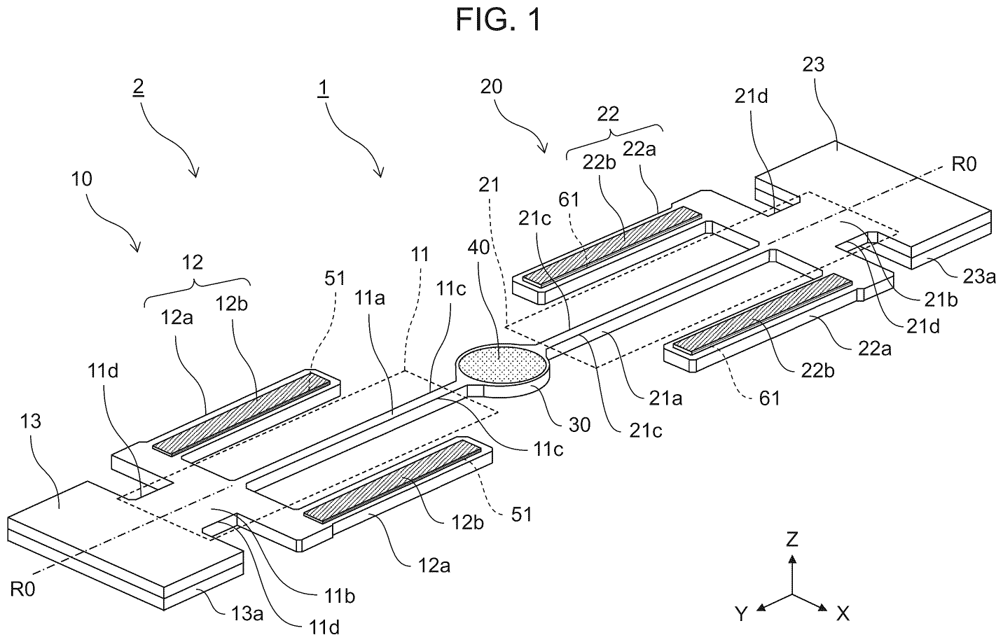

FIG. 1 is a perspective view schematically illustrating a configuration of drive element 1.

Drive element 1 includes first drive body 10, second drive body 20, and movable part 30. Movable part 30 has an upper surface on which reflecting surface 40 is disposed to form optical deflection element 2. Drive element 1 has a shape symmetrical with respect to the X-axis direction and the Y-axis direction in plan view.

First drive body 10 and second drive body 20 turn movable part 30 about turn axis R0 in response to a drive signal supplied from a drive circuit (not illustrated). Reflecting surface 40 reflects light incident from above movable part 30 in a direction corresponding to a swing angle of movable part 30. Consequently, the light (e.g., laser light) incident on reflecting surface 40 is deflected and swept as movable part 30 is turned. Movable part 30 and reflecting surface 40 may be formed of the same member.

First drive body 10 includes support part 11, drive part 12, and fixture 13.

Support part 11 supports drive part 12. Support part 11 includes first support part 11a and second support part 11b.

First support part 11a extends along turn axis R0 to be connected at one end (end part on the negative side on the Y-axis) to movable part 30 and at the other end (end part on the positive side on the Y-axis) to second support part 11b. First support part 11a has a rod shape (beam shape). First support part 11a has a cross section taken along the X-Z plane at its center, the cross section having a substantially square shape. Second support part 11b extends along turn axis R0 to be connected at one end (end part on the negative side on the Y-axis) to the other end (end part on the positive side on the Y-axis) of first support part 11a and at the other end (end part on the positive side on the Y-axis) to fixture 13. Second support part 11b has a plate shape.

Drive part 12 turns movable part 30 about turn axis R0. Drive part 12 includes a pair of arms 12a disposed symmetrically across turn axis R0, and piezoelectric drive part 12b disposed on arm 12a.

Arm 12a includes a part extending in the Y-axis direction and a part extending in the X-axis direction, the parts being combined in an L shape. The part of arm 12a extending in the X-axis direction is connected at an end part to support part 11. Piezoelectric drive part 12b is formed on an upper surface of arm 12a. Piezoelectric drive part 12b drives arm 12a on which piezoelectric drive part 12b is disposed.

Fixture 13 is for fixing drive element 1 to an installation surface. Fixture 13 has a larger thickness than support part 11. Fixture 13 is installed with its lower surface on the installation surface.

Second drive body 20 includes support part 21, drive part 22, and fixture 23.

Second drive body 20 is similar in configuration to first drive body 10. First drive body 10 and second drive body 20 are disposed opposite to each other across movable part 30. Support part 11 of first drive body 10 and support part 21 of second drive body 20 are each connected to movable part 30. Support part 11 includes side 11c located at its outer edge and support part 21 includes side 21c located at its outer edge, the sides being parallel to turn axis R0 as illustrated in FIG. 1. Second support part 11b includes side 11d and second support part 21b includes side 21d, the sides being parallel to turn axis R0 as illustrated in FIG. 1.

Fixture 13 of first drive body 10 and fixture 23 of second drive body 20 may be connected to each other to form a frame shape. This configuration includes support part 11 and support part 21, drive part 12 and drive part 22, movable part 30, and reflecting surface 40, which are positioned inside the frame shape of fixture 13 and fixture 23.

The pair of arms 12a constitutes a tuning fork vibrator. A pair of arms 22a also constitutes a tuning fork vibrator. First drive body 10 includes support part 11 that is turned about turn axis R0 when the pair of arms 12a is driven by two piezoelectric drive parts 12b. Second drive body 20 includes support part 21 that is turned about turn axis R0 when the pair of arms 22a is driven by two piezoelectric drive parts 22b. Movable part 30 is turned when support part 11 and support part 21 are controlled to turn in the same direction.

Piezoelectric drive part 12b has a stacked structure in which an electrode layer is disposed on each of upper and lower surfaces of piezoelectric thin film 51 having a predetermined thickness. Piezoelectric drive part 22b has a stacked structure in which an electrode layer is disposed on each of upper and lower surfaces of piezoelectric thin film 61 having a predetermined thickness. Piezoelectric thin film 51 and piezoelectric thin film 61 are each made of a piezoelectric material having a high piezoelectric constant, such as lead zirconate titanate (PZT). An electrode is made of a material having low electric resistance and high heat resistance, such as platinum (Pt) or gold (Au). When a layer structure including piezoelectric thin film 51, and upper and lower electrodes on the upper surface of arm 12a by a sputtering method or the like, piezoelectric drive part 12b is disposed on the upper surface of arm 12a. When a layer structure including piezoelectric thin film 61, and upper and lower electrodes on an upper surface of arm 22a by a sputtering method or the like, piezoelectric drive part 22b is disposed on the upper surface of arm 22a.

Drive element 1 has a base material identical in contour to drive element 1 in plan view and constant in thickness. The base material has an upper surface on which piezoelectric drive part 12b, piezoelectric drive part 22b, and reflecting surface 40 are each disposed in a corresponding region. The base material includes fixture 13 with a lower surface on which layer 13a made of a predetermined material is further formed to increase a thickness of fixture 13. The base material includes fixture 23 with a lower surface on which layer 23a made of a predetermined material is further formed to increase a thickness of fixture 23. Thus, drive element 1 has a constant thickness other than a region where layer 13a and layer 23a are each formed. Layer 13a and layer 23a may be each made of a material different from the base material, or may be each made of the same material as the base material.

The base material of drive element 1 is integrally made of silicon (Si), for example. Besides the silicon, the base material may be made of another material. The base material is preferably made of a material having high mechanical strength and Young's modulus, such as metal, a crystalline body, glass, or resin. Available examples of the material include titanium, stainless steel, elinvar, and brass alloy other than the silicon. The same applies to materials of layer 13a of fixture 13 and layer 23a of fixture 23.

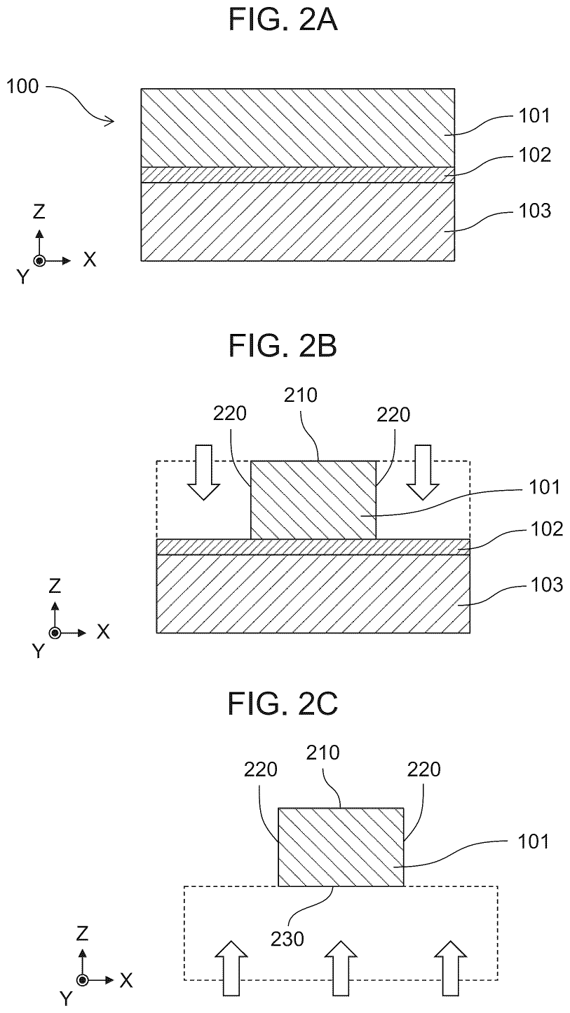

FIGS. 2A, 2B, and 2C are each a diagram schematically illustrating a procedure for molding the base material of drive element 1. FIGS. 2A to 2C each illustrate a cross section of drive element 1 taken along the X-Z plane.

As illustrated in FIG. 2A, the base material of drive element 1 is formed by processing silicon on insulator (SOI) substrate 100. SOI substrate 100 has a structure in which device layer 101, oxide film layer 102, and handle layer 103 are stacked in this order from above. Device layer 101 and handle layer 103 are each made of silicon (Si), and oxide film layer 102 is made of silicon dioxide (SiO₂).

As illustrated in FIG. 2B, device layer 101 is etched from its upper surface to be identical in contour to drive element 1 in plan view by removing device layer 101 in an unnecessary part. Consequently, device layer 101 is left in the same contour range as drive element 1, and upper surface 210 and side surface 220 are formed on this device layer 101.

From a state of FIG. 2B, handle layer 103 is etched from its lower surface to be identical in contour to fixture 13 and fixture 23 in plan view to remove handle layer 103. Then, oxide film layer 102 is etched from its lower surface to be identical in contour to fixture 13 and fixture 23 in plan view to remove oxide film layer 102. Consequently, handle layer 103 and oxide film layer 102 are removed from a region other than fixture 13 and fixture 23, and lower surface 230 is formed on device layer 101 other than fixture 13 and fixture 23 as illustrated in FIG. 2C. Meanwhile, handle layer 103 and oxide film layer 102 are not removed from a region of each of fixture 13 and fixture 23. Consequently, fixture 13 and fixture 23 are each increased in thickness as described above.

In the present exemplary embodiment, side surface 220 of device layer 101 illustrated in FIG. 2C is formed by etching of the Bosch process. In the Bosch process, an etching step is repeatedly performed to form a plurality of recesses (scallops) in device layer 101. A plurality of recesses as described above is formed in side surface 220 of device layer 101 while extending in a horizontal direction and being disposed side by side in a thickness direction of device layer 101.

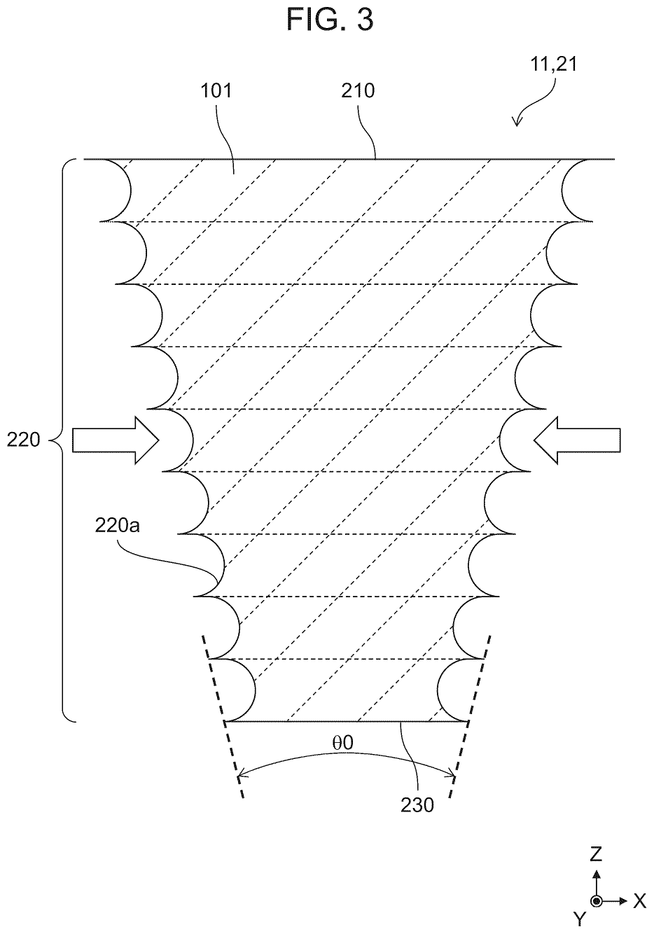

An investigation by the inventors has revealed that when support part 11 or support part 21 is twisted by turn of movable part 30, stress concentrates near the center in the thickness direction of side surface 220 of support part 11 or side surface 220 of support part 21. When this kind of stress concentration occurs, a large recess formed in side surface 220 of support part 11 or side surface 220 of support part 21 may cause breakage starting from the recess near the center of side surface 220 of support part 11 or side surface 220 of support part 21. This phenomenon will be described with reference to a comparative example of FIG. 3.

FIG. 3 is a diagram schematically illustrating a cross section of support part 11 or support part 21 according to the comparative example, taken along a plane parallel to the X-Z plane.

As illustrated in FIG. 3, support part 11 and support part 21 of the comparative example each include upper surface 210, side surface 220, and lower surface 230, which are formed by the procedure described with reference to FIGS. 2A to 2C. When side surface 220 is formed by the Bosch process, a plurality of recesses 220a is formed in side surface 220 while aligning in the thickness direction (Z-axis direction). One recess is formed corresponding to one etching step. Each recess 220a is recessed toward the inside of support part 11 and the inside of support part 21. The plurality of recesses 220a is disposed side by side in a direction in the X-Z plane, the direction being inclined inward and downward with respect to the Z-axis direction. Both side surfaces 220 are inclined at an inclination angle (taper angle) of θ0 therebetween.

When recess 220a has a certain size as in the comparative example, stress having concentrated near the center of side surface 220 in the thickness direction as indicated by a white arrow in FIG. 3 may cause breakage starting from recess 220a near the center of support part 11 or support part 21.

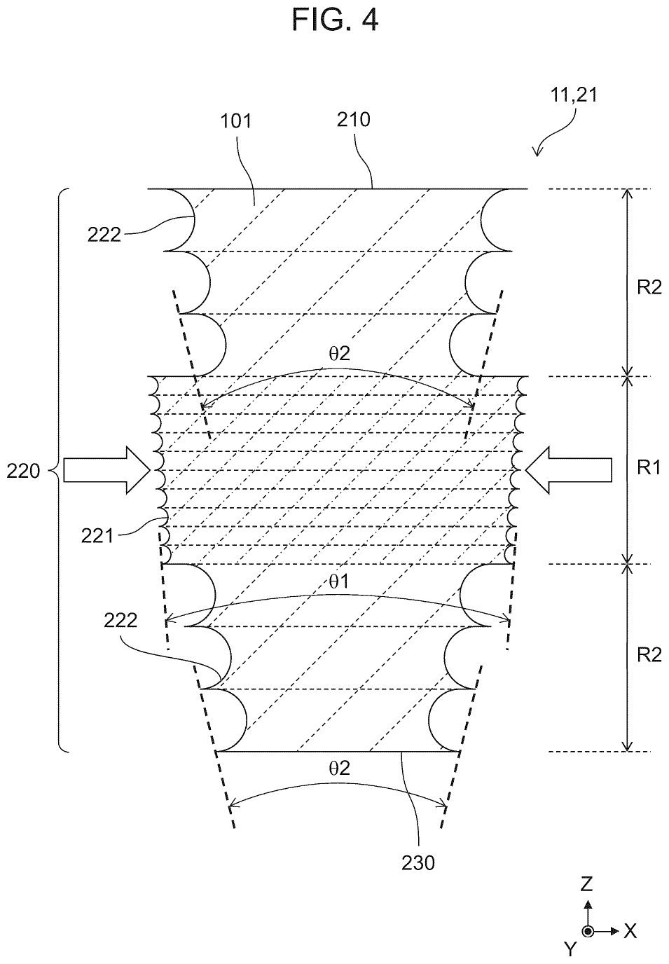

In contrast, etching by the Bosch process is performed in the exemplary embodiment to form a first recess in the first region including the center where the stress is most concentrated when support part 11 or support part 21 is twisted, the first recess having a smaller size than a second recess formed in the second region other than the first region. Consequently, strength near the center of side surface 220 is increased for support part 11 or support part 21 to enable suppressing breakage in side surface 220 of support part 11 or side surface 220 of support part 21 due to stress concentration. A configuration and an effect of the exemplary embodiment will be described with reference to FIG. 4.

FIG. 4 is a diagram schematically illustrating a cross section of support part 11 or support part 21 according to the exemplary embodiment, taken along a plane parallel to the X-Z plane.

As illustrated in FIG. 4, support part 11 and support part 21 of the exemplary embodiment each include upper surface 210, side surface 220, and lower surface 230, which are formed by the procedure described with reference to FIGS. 2A to 2C. When side surface 220 is formed by the Bosch process, a plurality of recesses 221 and a plurality of recesses 222 are formed in side surface 220 in the thickness direction (Z-axis direction). Each of recesses 221 and recesses 222 formed in side surface 220 is recessed toward the inside of support part 11 and the inside of support part 21, and has an arc shape as viewed in the Y-axis direction. That is, each of recesses 221 and recesses 222 has a shape of a side surface of a cylinder extending in a direction away from movable part 30, specifically, extending parallel to turn axis R0.

Etching by the Bosch process is performed in the exemplary embodiment to form recess 221 in first region R1 including the center of the side surface of the support part in the thickness direction, recess 221 having a smaller size than recess 222 formed in second region R2 other than first region R1. Second region R2 includes regions above and below first region R1 together.

The plurality of recesses 221 and 222 is disposed side by side in a direction in the X-Z plane, the direction being inclined inward and downward with respect to the Z-axis direction. Both side surfaces 220 in first region R1 are inclined at an inclination angle (taper angle) of θ1 therebetween, and both side surfaces 220 in second region R2 are inclined at an inclination angle (taper angle) of θ2 therebetween. As described above, when etching by the Bosch process is performed to cause recess 221 in first region R1 to be smaller than recess 222 in second region R2, taper angle θ1 becomes smaller than taper angle θ2.

When recess 221 near the center is formed small as described above, strength near the center is enhanced. Consequently, even when stress concentrates near the center of side surface 220 in the thickness direction as indicated by a white arrow in FIG. 4, breakage starting from recess 221 near the center of support part 11 or support part 21 can be prevented from occurring.

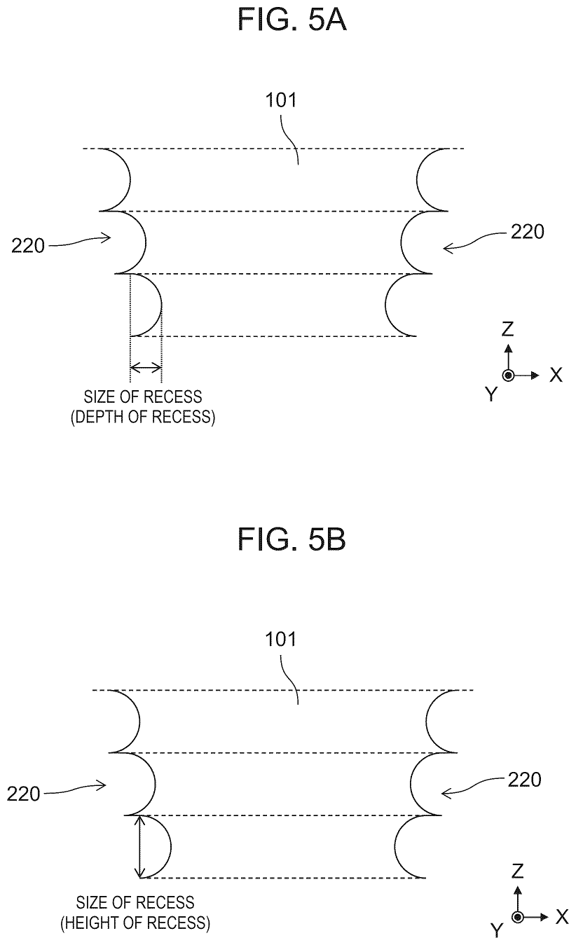

FIG. 5A is a schematic diagram illustrating an example in which a recess formed in a side surface according to the exemplary embodiment has a size corresponding to a depth of the recess. FIG. 5B is a schematic diagram illustrating an example in which a recess formed in a side surface according to the exemplary embodiment has a size corresponding to a height of the recess.

As illustrated in FIG. 5A, the recess formed in side surface 220 may have a size corresponding to a depth of the recess (a radius or diameter of an arc part), for example. As illustrated in FIG. 5B, the recess formed in side surface 220 may have a size corresponding to a height of the recess. The etching by the Bosch process enables forming a large recess by increasing the amount of etching per one etching step, and a small recess by reducing the amount of etching.

To change the amount of etching, speed (etching rate) for forming one recess is changed, for example. When the etching rate in first region R1 is reduced to lower than the etching rate in second region R2, recess 221 can be formed smaller than recess 222.

The etching of the Bosch process is plasma etching in which ions are incident on device layer 101. High-frequency power for controlling ion irradiation energy in the plasma etching defines intensity of the etching to define a size of a recess to be formed in side surface 220. Thus, when the high-frequency power during forming of first region RI is reduced smaller than the high frequency power during forming of second region R2, recess 221 can be formed smaller than recess 222.

When foreign matter (such as particles) adheres to a processed surface during etching, device layer 101 is not appropriately processed because the foreign matter serves as a mask to generate an Si residue in a needle shape. In contrast, when high-frequency power higher than that in first region R1 is applied in second region R2 as described above, ions incident on the processed surface in second region R2 are accelerated to facilitate removal of the foreign matter adhering to the processed surface. Consequently, the Si residue can be reduced in second region R2, so that generation of defective drive element 1 can be suppressed.

### EFFECT OF EXEMPLARY EMBODIMENT

### The Exemplary Embodiment Enables Achieving Effects Below

As illustrated in FIG. 4, the plurality of recesses 221 and the plurality of recesses 222 extending parallel to turn axis R0 are formed in side surface 220 of support part 11 and side surface 220 of support part 21 side by side in the thickness direction of support part 11 and support part 21. Recess 221 formed in first region R1 including at least the center in the thickness direction has a smaller size than recess 222 formed in second region R2 other than first region R1.

When torsion occurs in support part 11 or support part 21 due to turn of movable part 30, stress concentrates near the center of side surface 220 of support part 11 or support part 21. At this time, when recess 220a formed in each of side surface 220 of support part 11 and side surface 220 of support part 21 is large in size as in the comparative example illustrated in FIG. 3, breakage may occur starting from recess 220a near the center of side surface 220. In contrast, recess 221 formed in first region R1 including the center where the stress is most concentrated when support part 11 or support part 21 is twisted has a smaller size than recess 222 formed in second region R2 other than first region R1 in the exemplary embodiment as illustrated in FIG. 4. Consequently, strength near the center is increased to enable suppressing breakage in side surface 220 of support part 11 or side surface 220 of support part 21 due to stress concentration.

Here, when SOI substrate 100 is etched by the Bosch process to form an outer shape of drive element 1 including support part 11 and support part 21, the amount of etching per etching step needs to be reduced to further reduce a size of a recess (scallop) to be formed in side surface 220 after the etching. Thus, reducing the recess (scallop) in size increases the number of etching cycles necessary for etching device layer 101 to form the outer shape of drive element 1. Consequently, the etching rate decreases to deteriorate productivity of drive element 1. In contrast, recess 222 (scallop) large in size is formed in second region R2 other than first region R1 in the exemplary embodiment instead of forming recess 221 (scallop) small in size in the entire side surface 220. Consequently, deterioration in productivity of drive element 1 can be suppressed while breakage near the center due to stress concentration is suppressed.

As illustrated in FIG. 4, second regions R2 are disposed above and below first region R1. Second region R2 above first region R1 extends to an upper end of each of side surface 220 of support part 11 and side surface 220 of support part 21, and second region R2 below first region R1 extends to a lower end of each of side surface 220 of support part 11 and side surface 220 of support part 21.

This configuration allows small recess 221 (scallop) to be formed only near the center, so that deterioration in productivity of drive element 1 can be effectively suppressed.

Side surface 220 is formed by the Bosch process to allow first region R1 to have a lower etching rate than an etching rate of second region R2.

This configuration enables recess 221 in first region R1 to have a smaller size than recess 222 in second region R2. Second region R2 has a higher etching rate than an etching rate of first region R1, so that deterioration in productivity of drive element 1 can be suppressed.

As illustrated in FIG. 1, support part 11 includes first support part 11a and second support part 11b, and drive part 12 includes the pair of arms 12a disposed across turn axis R0 and connected to support part 11, and piezoelectric drive part 12b disposed on arm 12a. Similarly, support part 21 includes first support part 21a and second support part 21b, and drive part 22 includes the pair of arms 22a disposed across turn axis R0 and connected to support part 21, and piezoelectric drive part 22b disposed on arm 22a.

Although this configuration causes first support part 11a and second support part 11b, or first support part 21a and second support part 21b to be twisted when arms 12a or arms 22a are driven, recess 221 (scallop) and recess 222 (scallop) are formed in side surface 220 of each of first support part 11a, second support part 11b, first support part 21a, and second support part 21b as described above. This configuration enables suppressing breakage due to stress concentration in side surface 220 of each of first support part 11a, second support part 11b, first support part 21a, and second support part 21b.

As illustrated in FIG. 1, optical deflection element 2 includes drive element 1 and reflecting surface 40 disposed on movable part 30.

This configuration enables light to be deflected and swept by reflecting surface 40.

### First Modification

Although second region R2 is disposed above and below first region R1 in the above exemplary embodiment, it may be disposed only below first region R1.

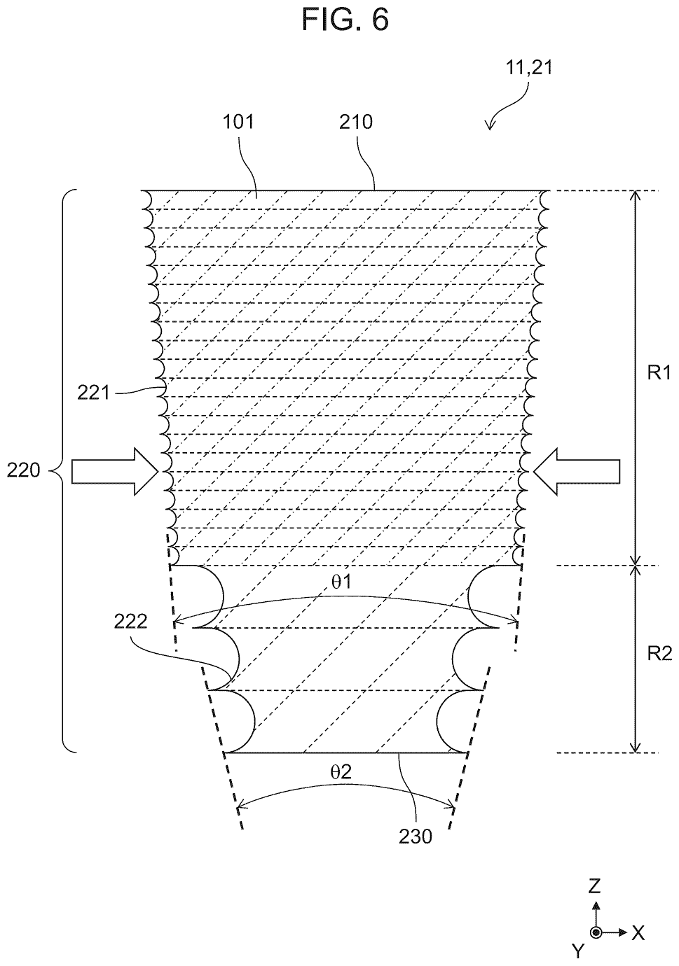

FIG. 6 is a diagram schematically illustrating a cross section of support part 11 or support part 21 according to a first modification, taken along a plane parallel to the X-Z plane.

In comparison with the exemplary embodiment illustrated in FIG. 4, the first modification includes first region R1 extending to an upper end of side surface 220 of each of support part 11 and support part 21, and second region R2 extending from a lower end of first region R1 to a lower end of side surface 220 of each of support part 11 and support part 21. Even this configuration allows recess 221 and recess 222 to be formed in side surface 220 in first region R1 and side surface 220 in second region R2, respectively, recess 221 being smaller than recess 222. As described above, when etching by the Bosch process is performed to cause recess 221 in first region R1 to be smaller than recess 222 in second region R2, taper angle θ1 becomes smaller than taper angle θ2.

The first modification allows small recess 221 (scallop) to be formed in first region R1 from near the center to the upper end of side surface 220 for each of support part 11 and support part 21, and thus can expand a range in which breakage due to stress concentration can be suppressed as compared with the above exemplary embodiment. Thus, the breakage due to stress concentration can be reliably suppressed.

### Second Modification

Although second region R2 is disposed above and below first region R1 in the above exemplary embodiment, it may be disposed only above first region R1.

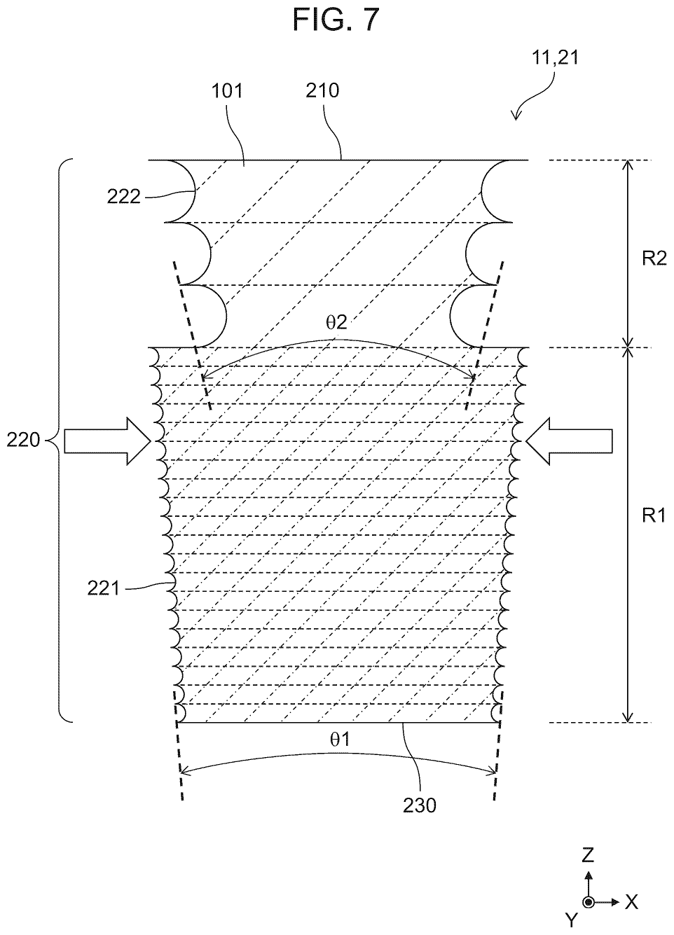

FIG. 7 is a diagram schematically illustrating a cross section of support part 11 or support part 21 according to a second modification, taken along a plane parallel to the X-Z plane.

In comparison with the exemplary embodiment illustrated in FIG. 4, the second modification includes first region R1 extending to a lower end of side surface 220 of each of support part 11 and support part 21, and second region R2 extending from an upper end of first region R1 to an upper end of side surface 220 of each of support part 11 and support part 21. Even this configuration allows recess 221 and recess 222 to be formed in side surface 220 in first region R1 and side surface 220 in second region R2, respectively, recess 221 being smaller than recess 222. As described above, when etching by the Bosch process is performed to cause recess 221 in first region R1 to be smaller than recess 222 in second region R2, taper angle θ1 becomes smaller than taper angle θ2.

The second modification allows small recess 221 (scallop) to be formed in first region R1 from near the center to the lower end of side surface 220 for each of support part 11 and support part 21, and thus can expand a range in which breakage due to stress concentration can be suppressed as compared with the above exemplary embodiment. Thus, the breakage due to stress concentration can be reliably suppressed.

### Third Modification

The above exemplary embodiment allows only second region R2 provided with recess 222 having a predetermined size to be disposed above first region R1, and only second region R2 provided with recess 222 having a predetermined size to be disposed below first region R1. Besides this, a plurality of regions provided with recesses different in size may be disposed above first region R1, and a plurality of regions provided with recesses different in size may be disposed below first region R1.

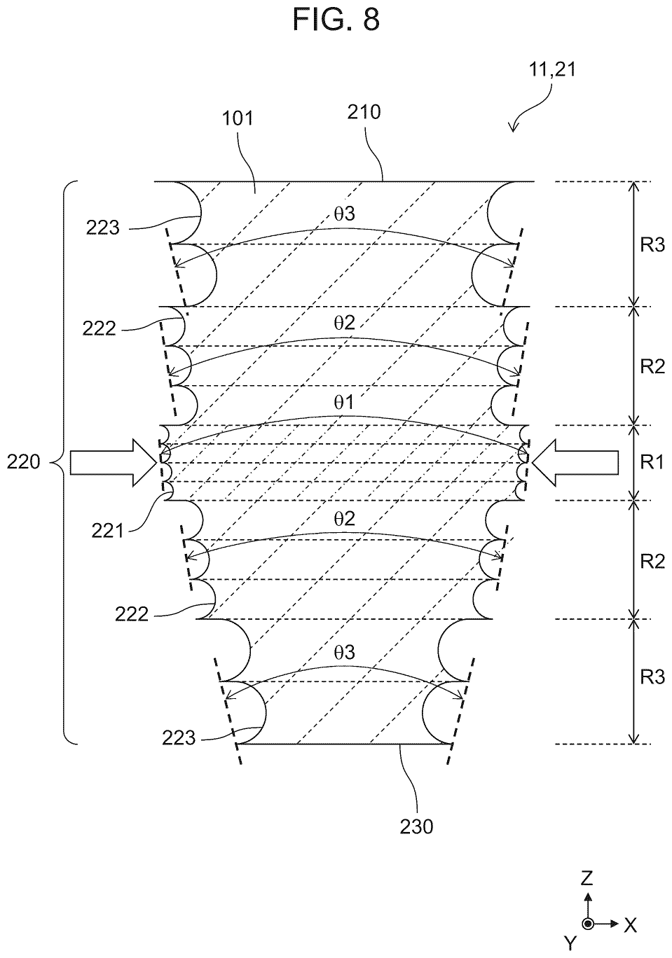

FIG. 8 is a diagram schematically illustrating a cross section of support part 11 or support part 21 according to a third modification, taken along a plane parallel to the X-Z plane.

In comparison with the exemplary embodiment illustrated in FIG. 4, the third modification includes second regions R2 disposed above and below first region R1, and third region R3 disposed not only above upper second region R2 but also below lower second region R2. Each of support part 11 and support part 21 includes upper second region R2 extending upward from an upper end of first region R1, and upper third region R3 extending from an upper end of second region R2 to an upper end of side surface 220. Each of support part 11 and support part 21 also includes lower second region R2 extending downward from a lower end of first region R1, and lower third region R3 extending from a lower end of second region R2 to a lower end of side surface 220.

Recess 221 is formed in side surface 220 in first region R1, recess 222 is formed in side surface 220 in second region R2, and recess 223 is formed in side surface 220 in third region R3. Recess 221 is smaller than recess 222, and recess 222 is smaller than recess 223. As with recess 221 and recess 222, recess 223 also has a shape of a side surface of a cylinder extending in a direction away from movable part 30, specifically, extending parallel to turn axis R0. Etching by the Bosch process is performed to achieve a size of each of recess 221, recess 222, and recess 223, as described above. Consequently, taper angle θ1 of first region R1 becomes smaller than taper angle θ2 of second region R2, and taper angle θ2 of second region R2 becomes smaller than taper angle θ3 of third region R3.

The third modification allows not only the recess of each of support part 11 and support part 21 to decrease in size stepwise from the upper end toward the center of side surface 220, but also the recess of each of support part 11 and support part 21 to decrease in size stepwise from the lower end toward the center of side surface 220. This configuration enables suppressing breakage due to stress in support part 11 and support part 21, the stress increasing from the upper end and the lower end toward the center in the thickness direction. Then, the recess of each of support part 11 and support part 21 gradually increases in size from the center to the upper end of side surface 220, and the recess of each of support part 11 and support part 21 gradually increases is size from the center to the lower end of side surface 220. Consequently, deterioration in productivity of drive element 1 can be effectively suppressed as compared with when every recess is formed large.

### Other Modifications

The exemplary embodiment of the present disclosure is not limited to the above exemplary embodiment and the first to third modifications.

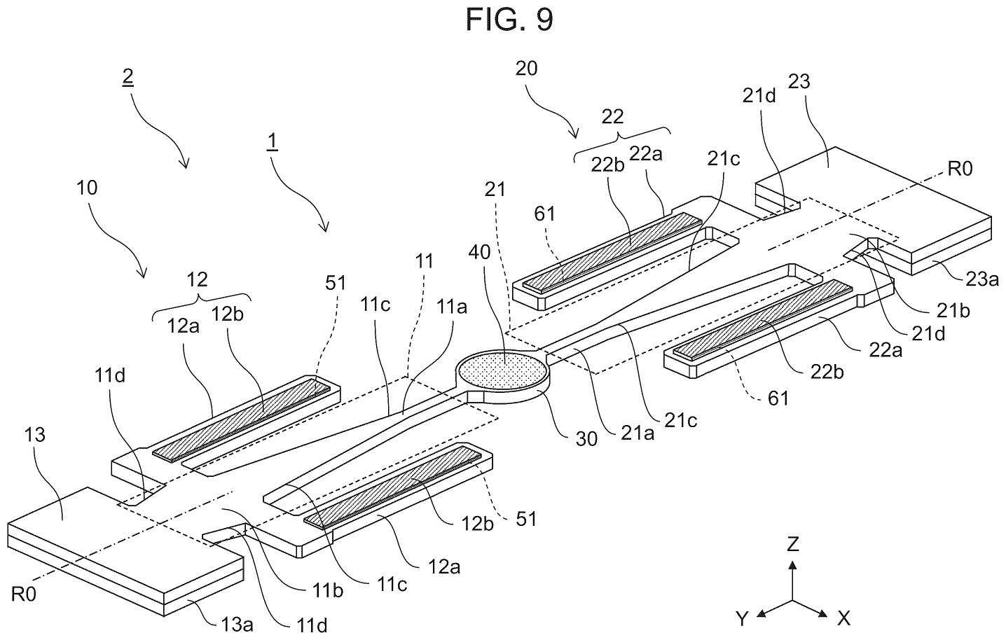

Although side 11c (referred to below as side 11c of support part 11 or side 11c) located at an outer edge of support part 11 and side 21c (referred to below as side 21c of support part 21, or side 21c) located at an outer edge of support part 21 with respect to turn axis R0 are parallel to turn axis R0 as illustrated in FIG. 1 in the above exemplary embodiment and modifications, side 11c of support part 11 or side 21c of support part 21 may have an angle with respect to turn axis R0. For example, side 11c of support part 11 and side 21c of support part 21 may be partially formed with an angle with respect to turn axis R0 as illustrated in FIG. 9.

FIG. 9 illustrates a configuration in which side 11c of first support part 11a, side 11c being near movable part 30, and side 21c of first support part 21a, side 21c being near movable part 30, extend in parallel to turn axis R0 as in the exemplary embodiment illustrated in FIG. 1. In comparison with the exemplary embodiment illustrated in FIG. 1, the configuration illustrated in FIG. 9 includes side 11c of first support part 11a, side 11c being located opposite to movable part 30, side 21c of first support part 21a, side 21c being located opposite to movable part 30, side 11d of second support part 11b, and side 21d of second support part 21b, which are each inclined with respect to turn axis R0 in the X-Y plane. The configuration illustrated in FIG. 9 shows that side 11c inclines toward turn axis R0 in one direction in the X-Y plane and side 11d inclines toward turn axis R0 in another direction in the X-Y plane, the one direction and the other direction being opposite to each other. The configuration illustrated in FIG. 9 also shows that side 21c inclines toward turn axis R0 in one direction in the X-Y plane and side 21d inclines toward turn axis R0 in another direction in the X-Y plane, the one direction and the other direction being opposite to each other. Even when support part 11 and support part 21 are formed as described above, a plurality of recesses formed in each of the side surface of support part 11 and side surface 220 of support part 21 extends in a direction away from movable part 30, as in the above exemplary embodiment and modifications. Even this configuration allows the first recess formed in the first region to be smaller than the second recess formed in the second region other than the first region, as in the above exemplary embodiment and first to third modifications. Consequently, strength near the center is increased to enable suppressing breakage in side surface 220 of support part 11 or side surface 220 of support part 21 due to stress concentration, as in the above exemplary embodiment and first to third modifications. Although the configuration illustrated in FIG. 9 shows that side 11c inclines toward turn axis R0 in one direction in the X-Y plane and side 11d inclines toward turn axis R0 in another direction in the X-Y plane, the one direction and the other direction being opposite to each other, side 11c and side 11d may incline toward turn axis R0 in the same direction in the X-Y plane. Similarly, side 21c and side 21d may incline toward turn axis R0 in the same direction in the X-Y plane.

Although recess 222 in upper second region R2 and recess 222 in lower second region R2 are equal in size in the above exemplary embodiment, recesses 222 in upper and lower second regions R2 may not be equal in size as long as recess 221 in first region R1 is smaller than recess 222 in each of upper and lower second regions R2.

For example, recess 222 in lower second region R2 may be larger than recess 222 in upper second region R2. This configuration enables recess 222 in lower second region R2 to be increased in size to larger than recess 222 in upper second region R2 by increasing an etching rate for lower second region R2 to higher than an etching rate for upper second region R2, or by increasing high-frequency power for lower second region R2 to higher than high-frequency power for upper second region R2.

When the high-frequency power for lower second region R2 is increased to larger than the high-frequency power for upper second region R2, foreign matter adhering to lower second region R2 is more easily removed. Consequently, an Si residue generated in lower second region R2 can be further reduced.

The third modification may include two regions different in size of recesses formed therein, or three or more regions different in size of recesses formed therein, which are disposed above first region R1 in the middle. Alternatively, the third modification may include two regions different in size of recesses formed therein, or three or more regions different in size of recesses formed therein, which are disposed below first region R1 in the middle. Even these configurations preferably include recesses gradually increasing in size upward from first region R1, and recesses gradually increasing in size downward from first region R1.

Although the region above first region R1 and the region below first region R1 are disposed in a vertically symmetrical manner about a central position of side surface 220 in the above exemplary embodiment and modifications, the regions may not necessarily be disposed symmetrically.

Although the central position of first region R1 is positioned at the central position of side surface 220 in a vertical direction in the above exemplary embodiment and modifications, the central position of first region R1 may be shifted from the central position of side surface 220. However, it is considered that stress applied to side surface 220 is distributed in a vertically symmetrical manner about the central position of side surface 220, so that the central position of first region R1 is preferably positioned at the central position of side surface 220.

Although the configuration of FIG. 4, FIG. 6, FIG. 7, or FIG. 8 is applied to every side surface 220 of support part 11 and support part 21 in the above exemplary embodiment and modifications, the configuration of FIG. 4, FIG. 6, FIG. 7, or FIG. 8 may be applied only to first support part 11a and first support part 21a of support part 11 and support part 21. This is because stress concentration caused by torsion becomes significant in first support part 11a or first support part 21a. However, when first support part 11a and first support part 21a, and second support part 11b and second support part 21b, are separately etched by the Bosch process with different settings, a manufacturing procedure becomes complicated. Thus, the configuration of FIG. 4, FIG. 6, FIG. 7, or FIG. 8 is preferably applied to every side surface 220 of support part 11 and support part 21, more specifically, to every side surface 220 of drive element 1.

Although the configuration of FIG. 4, FIG. 6, FIG. 7, or FIG. 8 is applied to side surfaces 220 of support part 11 and support part 21 of drive element 1 in the above exemplary embodiment and modifications, the configuration may be applied to a digital micromirror device (DMD) that is one of MEMS devices. Even in the DMD, a support part (torsion hinge) connected to a mirror is twisted and driven, and thus stress concentrates near the center of a side surface of the support part in its thickness direction. Thus, when the side surface of the support part is formed by etching of the Bosch process, strength near the center is increased by applying the configuration of FIG. 4, FIG. 6, FIG. 7, or FIG. 8 to the side surface. Consequently, breakage in the side surface of the support part of the DMD due to stress concentration can be suppressed.

Although drive element 1 is used as optical deflection element 2 in the above exemplary embodiment and modifications, it may be used as an element other than the optical deflection element. When drive element 1 is used as an element other than the optical deflection element, reflecting surface 40 may not be disposed on movable part 30, and another member other than reflecting surface 40 may be disposed.

Besides this, various modifications can be appropriately made to the exemplary embodiment of the present disclosure within the scope of the technical idea disclosed in the scope of claims.

### SUPPLEMENTARY NOTE

Techniques below are disclosed by the description of the above exemplary embodiment.

### Technique 1

A drive element including:
a movable part allowed to be turned about a turn axis;
a fixture;
a support part extending along the turn axis and connecting the movable part and the fixture; and
a drive part that turns the movable part about the turn axis,
the support part including a side surface including a plurality of recesses, the plurality of recesses extending in a direction away from the movable part and being disposed side by side in a thickness direction of the support part, and
the plurality of recesses including a first recess formed in a first region including at least a center of the side surface of the support part in the thickness direction, and a second recess formed in a second region other than the first region of the side surface of the support part, the first recess having a smaller size than the second recess.

When torsion occurs in the support part due to a turn of the movable part, stress concentrates near the center of the side surface of the support part. At this time, when the recess formed in the side surface of the support part is large in size, breakage may occur starting from the recess near the center of the side surface. In contrast, the technique described above includes the first recess formed in the first region including the center where the stress is most concentrated when the support part is twisted, and the first recess having a smaller size than the second recess formed in the second region other than the first region. Consequently, strength near the center is increased to enable suppressing breakage in the side surface of the support part due to stress concentration.

### Technique 2

The drive element described in Technique 1, in which
the second region is disposed includes an upper second region disposed above the first region and a lower second region disposed below the first region,
the upper second region extends to an upper end of the side surface of the support part, and
the lower second region extends to a lower end of the side surface of the support part.

This technique allows a small recess (scallop) to be formed only near the center, so that deterioration in productivity of the drive element can be effectively suppressed.

### Technique 3

The drive element described in Technique 1, in which
the first region extends to an upper end of the side surface of the support part, and
the second region extends from a lower end of the first region to a lower end of the side surface of the support part.

This technique allows a small recess (scallop) to be formed in the first region from near the center to the upper end of the side surface of the support part, and thus can expand a range in which breakage due to stress concentration can be suppressed. Thus, the breakage due to stress concentration can be reliably suppressed.

### Technique 4

The drive element described in Technique 1, in which
the first region extends to a lower end of the side surface of the support part, and
the second region extends from an upper end of the first region to an upper end of the side surface of the support part.

This technique allows a small recess (scallop) to be formed in the first region from near the center to the lower end of the side surface of the support part, and thus can expand a range in which breakage due to stress concentration can be suppressed. Thus, the breakage due to stress concentration can be reliably suppressed.

### Technique 5

The drive element described in any one of Techniques 1 to 4, in which the side surface in the first region has a smaller taper angle than a taper angle of the side surface in the second region.

### Technique 6

The drive element described in any one of Techniques 1 to 5, in which the side surface is formed by a Bosch process to allow the first region to have a lower etching rate than an etching rate of the second region.

This technique enables the first recess in the first region to have a smaller size than the second recess in the second region. Then, the second region has a higher etching rate than the etching rate of the first region, so that deterioration in productivity of the drive element can be suppressed.

### Technique 7

The drive element described in any one of Techniques 1 to 6, in which the support part is made of silicon (Si).

### Technique 8

The drive element described in any one of Techniques 1 to 7, in which
the support part includes:
a first support part having one end connected to the movable part; and
a second support part having one end connected to another end of the first support part and another end connected to the fixture, and
the drive part includes:
a pair of arms disposed across the turn axis and connected to the support part; and
a piezoelectric drive part disposed on each of the arms.

This technique enables suppressing breakage in the side surfaces of the first support part and the second support part due to stress concentration, even when the arms are driven to cause torsion in the first support part and the second support part, because of the recess (scallop) formed in the side surfaces of the first support part and the second support part as described above.

### Technique 9

An optical deflection element comprising:
a drive element described in any one of Techniques 1 to 8; and
a reflecting surface disposed on the movable part.

This technique enables light to be deflected and swept by the reflecting surface.

The drive element and the optical deflection element of the present disclosure enables suppressing breakage of a support part due to stress concentration caused by torsion of the support part. Thus, the drive element and the optical deflection element are improved in durability. As described above, the drive element and the optical deflection element of the present disclosure are industrially useful.

What is claimed is:

1. A drive element comprising:
a movable part allowed to be turned about a turn axis;
a fixture;
a support part extending along the turn axis and connecting the movable part and the fixture; and
a drive part that turns the movable part about the turn axis,
the support part including a side surface including a plurality of recesses, the plurality of recesses extending in a direction away from the movable part and being disposed side by side in a thickness direction of the support part, and
the plurality of recesses including a first recess formed in a first region including at least a center of the side surface of the support part in the thickness direction, and a second recess formed in a second region other than the first region of the side surface of the support part, the first recess having a smaller size than the second recess.

2. The drive element according to claim 1, wherein
the second region includes an upper second region disposed above the first region and a lower second region disposed below the first region,
the upper second region extends to an upper end of the side surface of the support part, and
the lower second region extends to a lower end of the side surface of the support part.

3. The drive element according to claim 1, wherein
the first region extends to an upper end of the side surface of the support part, and
the second region extends from a lower end of the first region to a lower end of the side surface of the support part.

4. The drive element according to claim 1, wherein
the first region extends to a lower end of the side surface of the support part, and
the second region extends from an upper end of the first region to an upper end of the side surface of the support part.

5. The drive element according to claim 1, wherein the side surface in the first region has a smaller taper angle than a taper angle of the side surface in the second region.

6. The drive element according to claim 1, wherein the side surface is formed by a Bosch process to allow the first region to have a lower etching rate than an etching rate of the second region.

7. The drive element according to claim 1, wherein the support part is made of silicon (Si).

8. The drive element according to claim 1, wherein
the support part includes:
a first support part having one end connected to the movable part; and
a second support part having one end connected to another end of the first support part and another end connected to the fixture, and
the drive part includes:
a pair of arms disposed across the turn axis and connected to the support part; and
a piezoelectric drive part disposed on each of the arms.

9. An optical deflection element comprising:
the drive element according to claim 1; and
a reflecting surface disposed on the movable part.
